(19) United States
(12) Patent Application Publication
(10) Pub. No.: US 2012/0306064 A1
(43) Pub. Date: Dec. 6, 2012

(54) CHIP PACKAGE

(75) Inventor: Tai-Hung Lin, Hsinchu City (TW)

(73) Assignee: NOVATEK MICROELECTRONICS CORP., Hsinchu (TW)

(21) Appl. No.: 13/585,802

(22) Filed: Aug. 14, 2012

Related U.S. Application Data
(62) Division of application No. 12/868,715, filed on Aug. 25, 2010.

(30) Foreign Application Priority Data
Sep. 18, 2009 (TW) 98131583

(51) Int. Cl. H01L 23/495

(52) U.S. Cl. 257/675; 257/E23.051

(57) ABSTRACT

A chip package including a lead frame, a heat sink, a chip and a molding compound is provided. The lead frame includes a chip pad and a plurality of leads, wherein the chip pad has a first surface and a second surface opposite thereto. The heat sink has a third surface and a fourth surface opposite thereto, wherein the lead frame is disposed on the third surface of the heat sink through the second surface of the chip pad, and the fourth surface of the heat sink is exposed. The chip is disposed on the first surface of the chip pad and electrically connected to each of the chip pad and the leads. The molding compound encapsulates the chip, the chip pad, the heat sink and a portion of each of the leads.

### CROSS-REFERENCE TO RELATED APPLICATION

This is a divisional application of and claims the priority benefit of U.S. application Ser. No. 12/868,715, filed on Aug. 25, 2010, now pending, which claims the priority benefit of Taiwan application serial no. 98131583, filed on Sep. 18, 2009. The entirety of each of the above-mentioned patent applications is hereby incorporated by reference herein and made a part of this specification.

### BACKGROUND OF THE INVENTION

1. Field of the Invention

The disclosure is related to a chip package, and in particular to a chip package having a heat sink.

2. Description of Related Art

The semiconductor industry is one of the fastest growing high-tech industries in recent years. As electronic technology advances, high-tech electronic industries are formed one after another, so that electronic products that are more user-friendly and have better functions are continually produced and developing towards the trend of being light weight, thin, short, and having a small volume. In the semiconductor industry, the production of integrated circuits (IC) mainly includes three stages: IC design, IC process, and IC package. The purpose of packaging is to prevent a chip from being affected by external temperature and moisture and being polluted by dust and to serve as a medium for electrical connections between the chip and external circuits.

In IC package processes, there are many types of package forms, wherein quad flat packages (QFP) have characteristics such as having a plurality of leads, a short outline, superb electrical characteristics, and low cost, and are hence a type of widely used package structure. Generally, during a QFP process, a chip is disposed on a lead frame which has a plurality of leads, the chip is connected to the leads through a wire bonding method, and a molding compound is formed to encapsulate the chip, the wires, and a portion of the leads. The chip is connected to ground, to a power source, and to a signal through the leads, so that the chip is connected to external circuits, and the molding compound protects the chip, the wires, and a portion of the leads from the external environment. As the QFP is widely used, one main issue in the semiconductor field is how to improve the package to make products more competitive.

### SUMMARY OF THE INVENTION

The disclosure provides a chip package process, so that there are superb electrical connections between a chip, a chip pad, and a heat sink.

The disclosure also provides a chip package which has superb heat dissipating abilities.

The disclosure provides a chip package process. First a lead frame is provided. The lead frame includes a chip pad and a plurality of leads, wherein the chip pad has a first surface and a second surface opposite thereto. The lead frame is disposed on a third surface of the heat sink through the second surface of the chip pad, and the chip pad is electrically connected to the heat sink. A chip is then disposed on the first surface of the chip pad, and is electrically connected to each of the chip pad and the leads. A molding compound is formed, so as to encapsulate the chip, the chip pad, the heat sink, and a portion of each of the leads, wherein the molding compound exposes a fourth surface of the heat sink, wherein the third surface and the fourth surface are opposite to each other.

According to an embodiment of the disclosure, the fourth surface of the heat sink is bonded to a bonding region of the electronic device, so that the chip is electrically connected to the electronic device through the chip pad and the heat sink.

According to an embodiment of the disclosure, a method of bonding the heat sink to the electronic device includes a surface mounting technology.

According to an embodiment of the disclosure, the bonding region of the electronic device has at least one through hole, so as to expose the heat sink after the heat sink is bonded to the electronic device.

According to an embodiment of the disclosure, the electronic device includes a circuit board, a testing pad, or a functional system.

According to an embodiment of the disclosure, the circuit board includes a plurality of solder pads arranged in an array in the bonding region.

According to an embodiment of the disclosure, a shortest distance between the electronic device and the fourth surface of the heat sink is from 0.05 mm to 0.15 mm.

According to an embodiment of the disclosure, the electronic device contacts the fourth surface of the heat sink.

According to an embodiment of the disclosure, an electrically conductive layer is formed between the chip pad and the heat sink.

According to an embodiment of the disclosure, the electrically conductive layer is a bonding glue or an electrically conductive tape.

According to an embodiment of the disclosure, the method of electrically connecting the chip to the chip pad and the leads includes wire bonding.

According to an embodiment of the disclosure, the heat sink has a central region and a peripheral region surrounding the central region, wherein the central region is an electrically conductive region, the peripheral region is an insulation region, and the chip pad is disposed on the central region.

According to an embodiment of the disclosure, the central region is a lowered region and the peripheral region is a level region, the lowered region has a depth, there is a height difference between the chip pad and a top of the leads, and the depth is less then the height difference.

According to an embodiment of the disclosure, the depth of the lowered region is greater than 0 mm and less than 0.294 mm.

According to an embodiment of the disclosure, an electroplating process is performed on the central region, so as to form an electrically conductive layer on a surface of the central region.

According to an embodiment of the disclosure, a material of the electrically conductive layer includes copper.

According to an embodiment of the disclosure, an anti-oxidizing layer is formed on the electrically conductive layer.

According to an embodiment of the disclosure, a method of forming the anti-oxidizing layer includes electrolysis electroplating or chemical electroplating.

According to an embodiment of the disclosure, a material of the anti-oxidizing layer includes nickel.

According to an embodiment of the disclosure, an insulating process is performed on the peripheral region.

According to an embodiment of the disclosure, the insulating process includes attaching an insulation tape on the peripheral region.

According to an embodiment of the disclosure, the insulating process includes selectively electroplating or performing an anodizing process on the peripheral region.

According to an embodiment of the disclosure, the following steps are performed prior to bonding the chip pad with the heat sink. First, the central region of the third surface and the fourth surface are masked by a masking layer, and a remaining surface of the heat sink is exposed. Next, an insulating process is performed on the heat sink which is partially masked, so as to form an insulation layer on the remaining surface of the heat sink. The masking layer is then removed.

According to an embodiment of the disclosure, the masking layer is a tape.

According to an embodiment of the disclosure, the insulating process includes attaching an insulation tape on the remaining surface.

According to an embodiment of the disclosure, the insulating process includes selectively electroplating or performing an anodizing process on the remaining surface.

According to an embodiment of the disclosure, after the masking layer is removed, an electroplating process is performed on the central region and the fourth surface, so as to form the electrically conductive layer on the central region and the fourth surface.

According to an embodiment of the disclosure, a material of the electrically conductive layer includes copper.

According to an embodiment of the disclosure, an anti-oxidizing layer is formed on the electrically conductive layer.

According to an embodiment of the disclosure, a method of forming the anti-oxidizing layer includes electrolysis electroplating or chemical electroplating.

According to an embodiment of the disclosure, a material of the anti-oxidizing layer includes nickel.

The disclosure also provides a chip package which includes a lead frame, a heat sink, a chip, and a molding compound. The lead frame includes a chip pad and a plurality of leads, wherein the chip pad has a first surface and a second surface opposite thereto. The heat sink has a third surface and a fourth surface opposite thereto, wherein the lead frame is disposed on the third surface of the heat sink through the second surface of the chip pad, and the fourth surface of the heat sink is exposed. A chip is disposed on the first surface of the chip pad, and is electrically connected to each of the chip pad and the leads. A molding compound encapsulates the chip, the chip pad, the heat sink, and a portion of each of the leads.

According to an embodiment of the disclosure, an electronic device is further included, wherein a bonding region of the electronic device is bonded to the fourth surface of the heat sink, so that the chip is electrically connected to the electronic device through the chip pad and the heat sink.

According to an embodiment of the disclosure, the heat sink is bonded to the electronic device through a surface mounting technology.

According to an embodiment of the disclosure, the bonding region of the electronic device has at least one through hole, so as to expose the heat sink after the heat sink is bonded to the electronic device.

According to an embodiment of the disclosure, the electronic device includes a circuit board, a testing pad, or a functional system.

According to an embodiment of the disclosure, the circuit board includes a plurality of solder pads arranged in an array in the bonding region.

According to an embodiment of the disclosure, a shortest distance between the electronic device and the fourth surface of the heat sink is from 0.05 mm to 0.15 mm.

According to an embodiment of the disclosure, the electronic device contacts the fourth surface of the heat sink.

According to an embodiment of the disclosure, the electrically conductive layer is further included between the chip pad and the heat sink.

According to an embodiment of the disclosure, the electrically conductive layer is a bonding glue or an electrically conductive tape.

According to an embodiment of the disclosure, the heat sink has a central region and a peripheral region surrounding the central region, wherein the central region is an electrically conductive region, the peripheral region is an insulation region, and the chip pad is disposed on the central region.

According to an embodiment of the disclosure, the central region is a lowered region and the peripheral region is a level region, the lowered region has a depth, there is a height difference between the chip pad and a top of the leads, and the depth is less then the height difference.

According to an embodiment of the disclosure, the depth of the lowered region is greater than 0 mm and less than 0.294 mm.

According to an embodiment of the disclosure, the electrically conductive layer is disposed on the central region and the fourth surface of the heat sink.

According to an embodiment of the disclosure, the electrically conductive layer is formed by an electroplating process.

According to an embodiment of the disclosure, a material of the electrically conductive layer includes copper.

According to an embodiment of the disclosure, an anti-oxidizing layer is further disposed on the electrically conductive layer.

According to an embodiment of the disclosure, the anti-oxidizing layer is formed by electrolysis electroplating or chemical electroplating.

According to an embodiment of the disclosure, a material of the anti-oxidizing layer includes nickel.

According to an embodiment of the disclosure, an insulation tape is attached on the peripheral region.

According to an embodiment of the disclosure, selective electroplating or an anodizing process is performed on the peripheral region.

According to an embodiment of the disclosure, selective electroplating or an anodizing process is performed on a remaining surface other than the third and fourth surfaces of the heat sink.

According to an embodiment of the disclosure, an insulation tape is attached on the remaining surface other than the third and fourth surfaces of the heat sink.

According to an embodiment of the disclosure, the heat sink includes a first portion and a second portion, a center of the first portion is a hollowed portion, the second portion is embedded in the hollowed portion of the first portion, and the chip pad is bonded to the second portion.

According to an embodiment of the disclosure, a material of the first portion includes aluminum.

According to an embodiment of the disclosure, a material of the second portion includes a material which is able to be plated with tin.

According to an embodiment of the disclosure, a material of the second portion includes copper.

According to an embodiment of the disclosure, an anti-oxidizing layer is disposed on a surface of the second portion.

According to an embodiment of the disclosure, a method of forming the anti-oxidizing layer includes electrolysis electroplating or chemical electroplating.

According to an embodiment of the disclosure, a material of the anti-oxidizing layer includes nickel.

According to an embodiment of the disclosure, an insulating process is performed on a surface of the first portion.

According to an embodiment of the disclosure, the insulating process includes attaching an insulation tape on the surface of the first portion.

According to an embodiment of the disclosure, the insulating process includes selectively electroplating or performing an anodizing process on the surface of the first portion.

In summary, according to the disclosure, there are superb electrical connections in the chip package and between the chip, the lead frame, and the heat sink used in the chip package process, and the bottom surface of the heat sink is exposed. Therefore, the chip package has superb heat dissipating abilities and the chip may be connected to ground, to a power source, or to a signal through the bottom surface of the heat sink, thereby being beneficial to increasing the variety of circuit designs.

In order to make the aforementioned and other objects, features and advantages of the disclosure comprehensible, embodiments accompanied with figures are described in detail below.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 is a schematic flowchart which shows a chip package process according to the first embodiment of the disclosure.

FIGS. 2A to 2D are schematic cross-sectional views which show the chip package process according to the first embodiment of the disclosure.

FIG. 3 is a schematic cross-sectional view of a chip package according to the second embodiment of the disclosure.

FIG. 4 is a schematic cross-sectional view of another chip package according to the second embodiment of the disclosure.

FIG. 5 is a schematic cross-sectional view of a chip package according to the third embodiment of the disclosure.

FIG. 6 is a schematic top view of an electronic device according to the third embodiment of the disclosure.

FIGS. 7A to 7C are schematic cross-sectional views which show a process of a heat sink according to the fourth embodiment of the disclosure.

FIG. 8 is a schematic cross-sectional view of a chip package according to the fourth embodiment of the disclosure.

FIG. 9 is a schematic cross-sectional view of a chip package according to the fifth embodiment of the disclosure.

### DESCRIPTION OF EMBODIMENTS

### First Embodiment

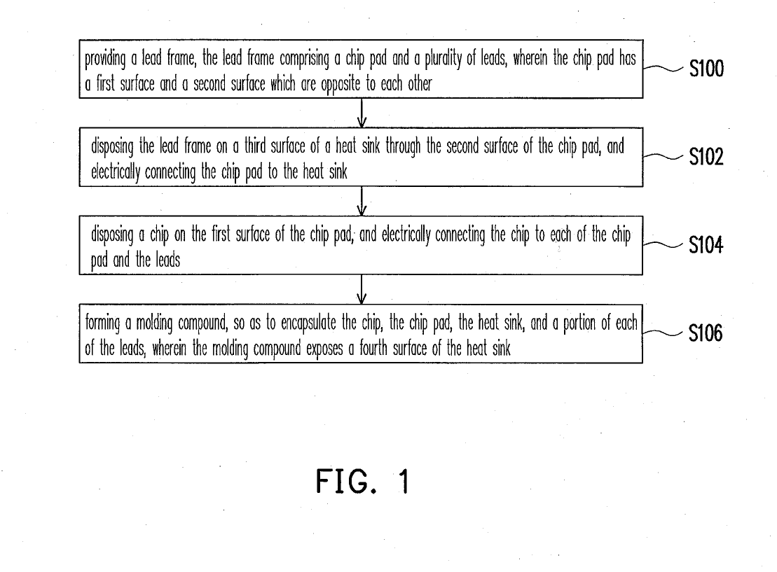

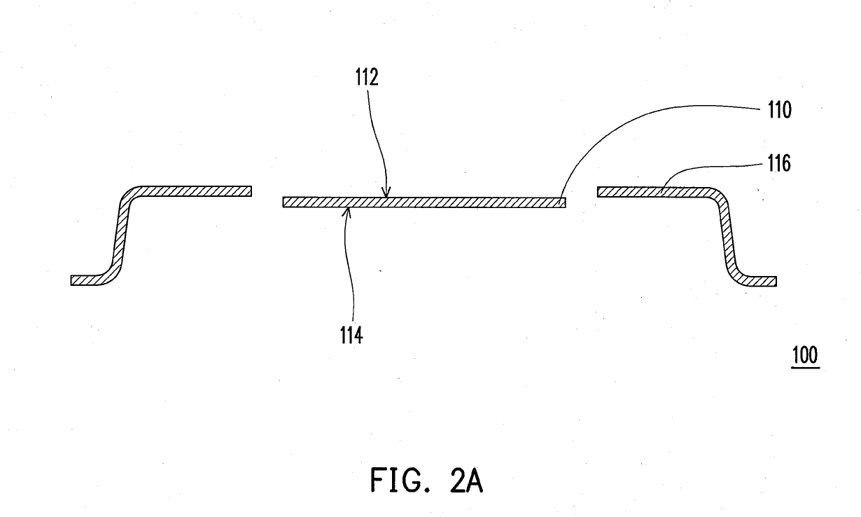

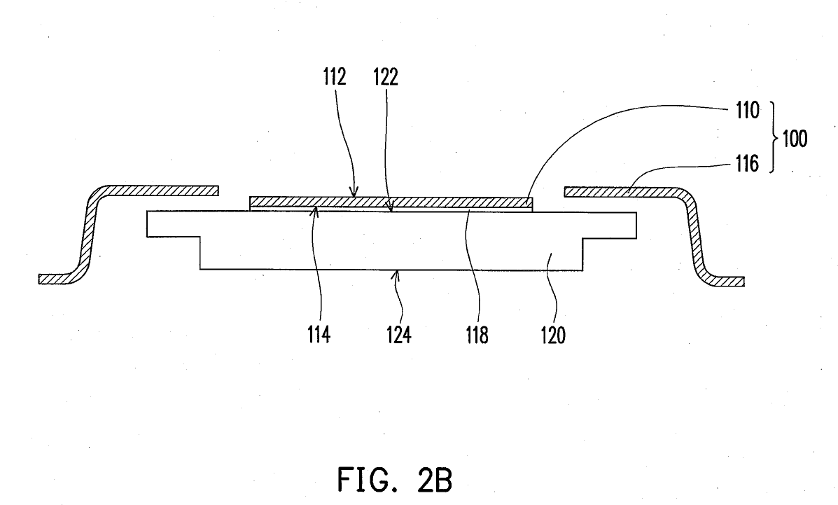

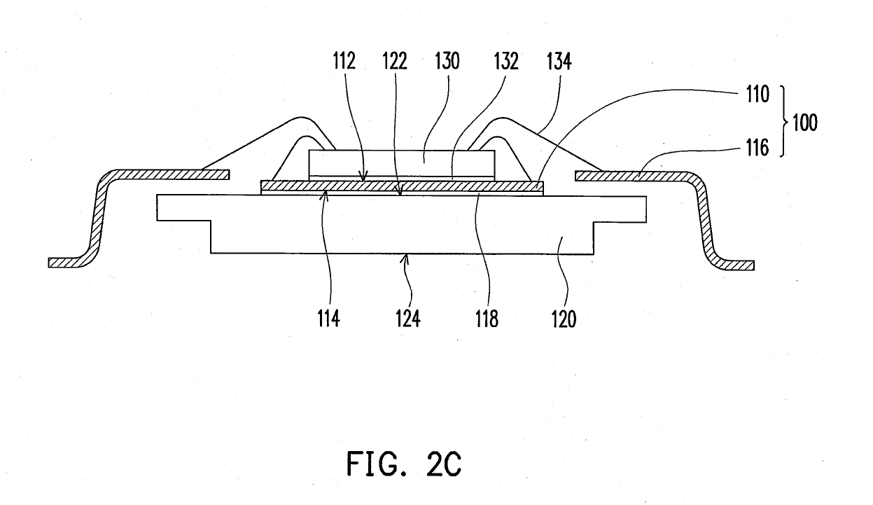

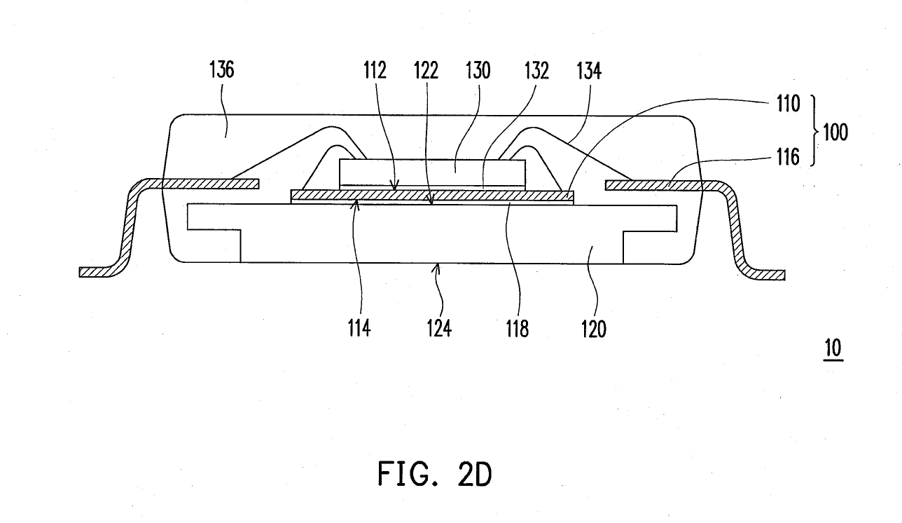

FIG. 1 is a schematic flowchart which shows a chip package process according to the first embodiment of the disclosure. FIGS. 2A to 2D are schematic cross-sectional views which show the chip package process according to the first embodiment of the disclosure.

Please refer to both FIGS. 1 and 2A. First, a step S100 is performed. A lead frame 100 is provided. The lead frame 100 includes a chip pad 110 and a plurality of leads 116, and the chip pad 110 has a first surface 112 and a second surface 114 opposite thereto. According to the present embodiment, the leads 116 surround the chip pad 110.

Please refer to both FIGS. 1 and 2B. A step S102 is performed. The lead frame 100 is disposed on a third surface 122 of a heat sink 120 through the second surface 114 of the chip pad 110, and the chip pad 110 is electrically connected to the heat sink 120. As shown in FIG. 2B, the heat sink 120 has a fourth surface 124 opposite to the third surface 122. According to the present embodiment, a material of the heat sink 120 is, for example, aluminum or an aluminum alloy, and the chip pad 110 is, for example, bonded to the heat sink 120 via an electrically conductive layer 118 such as an electrically conductive tape or a bonding glue. According to another embodiment, the chip pad 110 may directly contact the heat sink 120 and to be directly bonded with the heat sink 120 via physical forces (not shown).

Please refer to FIGS. 1 and 2C. Next, a step S104 is performed. A chip 130 is disposed on the first surface 112 of the chip pad 110, and the chip 130 is electrically connected to each of the chip pad 110 and the leads 116. According to the present embodiment, the chip 130 is, for example, fixated on the chip pad 110 via an electrically conductive layer 132 such as an electrically conductive tape or a bonding glue, and the chip 130 is, for example, electrically connected to the chip pad 110 and the leads 116 through a plurality of solder wires 134 by a wire bonding process.

Please refer to both FIGS. 1 and 2D. A step S106 is performed to form a molding compound 136 which encapsulates the chip 130, the chip pad 110, the heat sink 120, and a portion of each of the leads 116. The molding compound 136 exposes the fourth surface 124 of the heat sink 120. After completing the step S106, a chip package 10 as shown in FIG. 2D is formed.

Still referring to FIG. 2D, according to the present embodiment, the chip package 10 includes the lead frame 100, the heat sink 120, the chip 130, and the molding compound 136. The lead frame 100 includes the chip pad 110 and the leads 116, wherein the chip pad 110 has the first surface 112 and the second surface 114 opposite thereto. The heat sink 120 has the third surface 122 and the fourth surface 124 opposite thereto, wherein the lead frame 100 is disposed on the third surface 122 of the heat sink 120 through the second surface 112 of the chip pad 110, and the fourth surface 124 of the heat sink 120 is exposed. The chip 130 is disposed on the first surface 112 of the chip pad 110, and is electrically connected to each of the chip pad 110 and the leads 116. The molding compound 136 encapsulates the chip 130, the chip pad 110, the heat sink 120, and a portion of each of the leads 116. In addition, as shown in the structure of the heat sink 120, a portion in which the heat sink 120 contacts the chip pad 110 is termed a central region, and a remaining portion which surrounds the central region is termed a peripheral region, wherein the central region is, for example, an electrically conductive region, and the peripheral region is, for example, an insulation region. The chip 130, the lead frame 100, and the heat sink 120 are hence well electrically connected. Electrical resistance in between is, for example, less than 10 milliohms, and heat from the chip package 10 is dissipated from the fourth surface 124, so that the chip package 10 has superb heat dissipating abilities.

According to the present embodiment, the chip 130, the lead frame 100, and the heat sink 120 are well electrically connected, and the fourth surface 124 of the heat sink 120 is exposed. The chip package 10 hence has superb heat dissipating abilities and the chip 130 may be connected to ground, to a power source, or to a signal through the fourth surface 124 of the heat sink 120. For example, 80% to 100% of output towards ground from the chip 130 may be conducted through the fourth surface 124 of the heat sink 120. Therefore, the leads 116 which were originally used for connection to ground, to a power source, or to a signal are able to be used for other additional functions. In addition, the chip may be electrically connected to other electronic devices through the bottom surface of the heat sink, so as to have superb electrical connections to other electronic devices. Therefore, the chip package has superb heat dissipating abilities and provides additional functions and is suitable for being integrated with other electronic devices, so that products which utilize this chip package are more competitive.

### Second Embodiment

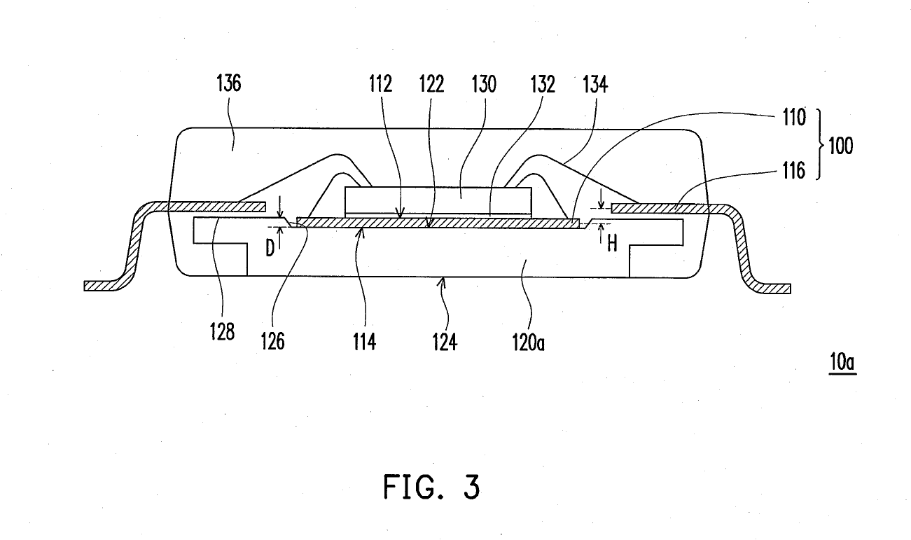

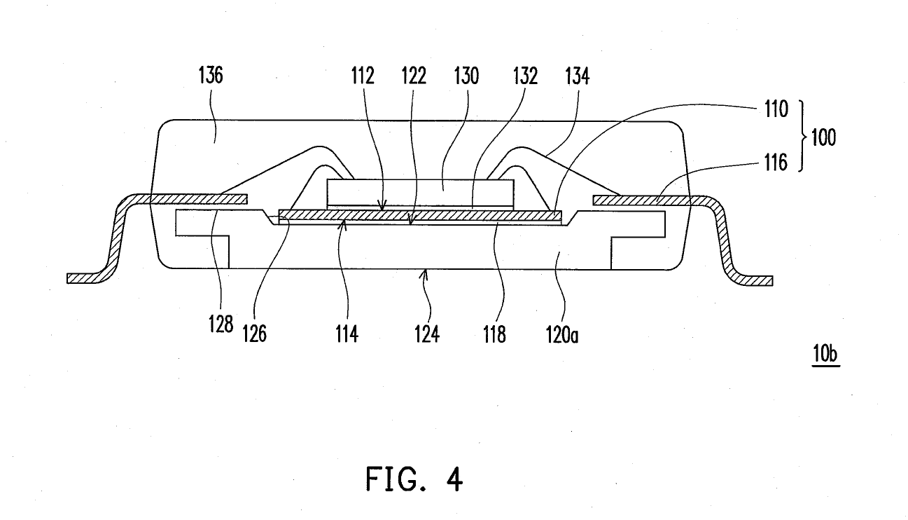

FIG. 3 is a schematic cross-sectional view of a chip package according to the second embodiment of the disclosure. FIG. 4 is a schematic cross-sectional view of another chip package according to the second embodiment of the disclosure. According to the present embodiment, structures and processes of a chip packages 10a and 10b are similar to those of the chip package 10 according to the first embodiment. The following only describes the differences in between.

Please refer to FIG. 3. According to the present embodiment, a heat sink 120a has, for example, a central region 126 and a peripheral region 128 surrounding the central region 126, wherein the central region 126 is an electrically conductive region, the peripheral region 128 is an insulation region, and the chip pad 110 is disposed on the central region 126. According to the present embodiment, the central region 126 is, for example, a lowered region which has a depth D, and the peripheral region 128 is, for example, a level region. It should be noted that in the chip package 10a, a difference in height between the chip pad 110 and a top of the leads 116 is a height H. It is preferable to design the depth D of the central region 126 to be less than the height H, so as to prevent the top of the leads 116 from touching the peripheral region 128 of the heat sink 128a. According to the present embodiment, the depth D of the central region 126 is greater than 0 mm and less than 0.29 mm. Moreover, according to the present embodiment, the chip pad 110 is disposed on the lowered central region 126, so that displacement between the heat sink 120a and the chip pad 110 caused by thermal expansion or other process factors is prevented, thereby ensuring tight bonding between the heat sink 120a and the chip pad 110. Contact electrical resistance between the heat sink 120a and the chip pad 110 is also reduced. In addition, during the process of forming the molding compound 136, the injected molding compound may become tilted due to a gap of excessive size between the lead frame 100 and the heat sink 120a, so that the molding compound 136 may be injected in a non-uniform manner. However, according to the present embodiment, by positioning the chip pad 110 in the central region 126 of the heat sink 120a, the gap between the lead frame 100 and the heat sink 120a is greatly reduced, thereby preventing the problem. Furthermore, according to the present embodiment, the heat sink 120a is exemplarily shown as being directly bonded to the chip pad 110 through physical forces; however, according to another embodiment as shown in FIG. 4, the heat sink 120a is bonded to the chip pad 110 through the electrically conductive layer 118 in the first embodiment.

According to the present embodiment, the central region 126 of the heat sink 120a enhances bonding reliability between the heat sink 120a and the chip pad 110, and is suitable for injection of the molding compound 136. Electrical connection effects between the chip 130, the chip pad 110, and the heat sink 120a are hence ensured, and heat dissipating abilities of the chip packages 10a and 10b are enhanced, so that products which utilize the chip packages 10a and 10b are more competitive.

### Third Embodiment

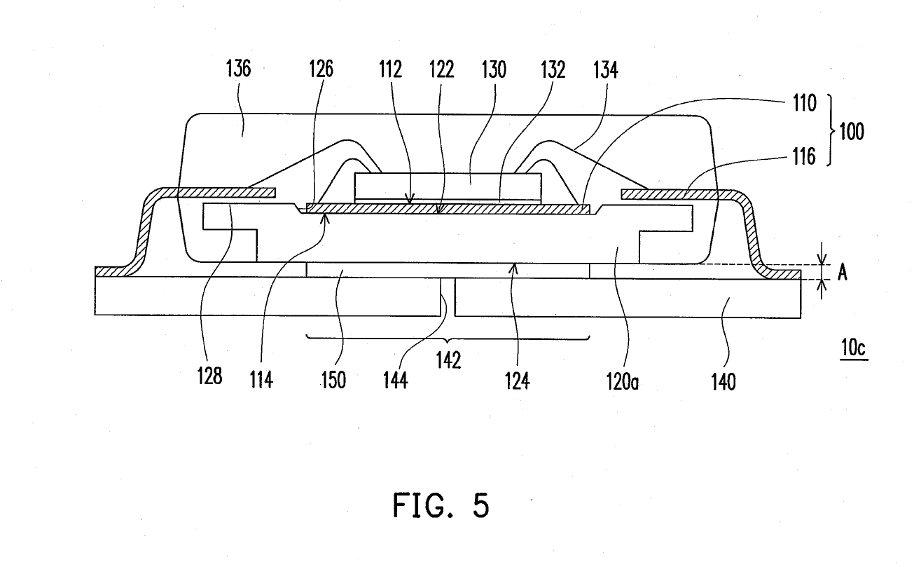

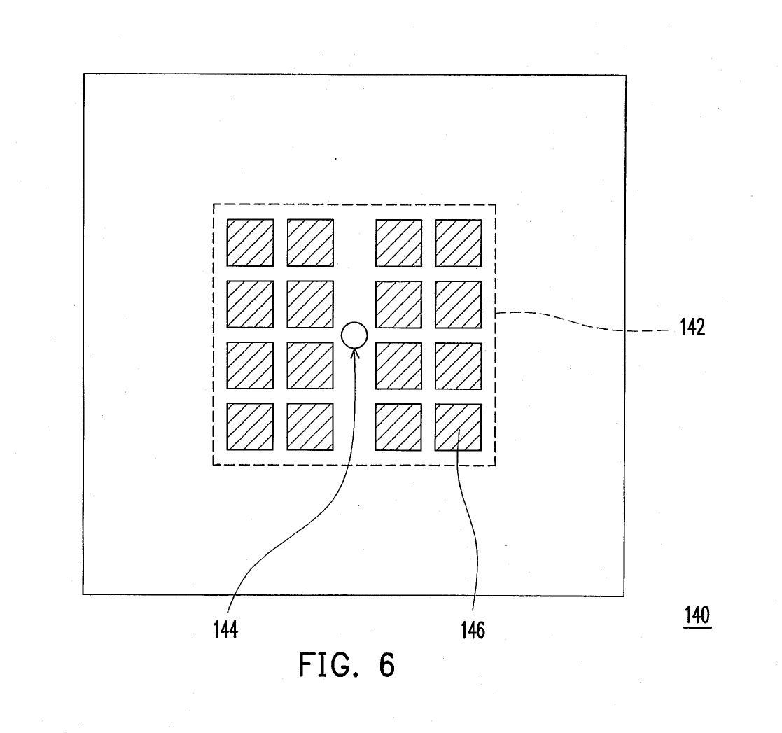

FIG. 5 is a schematic cross-sectional view of a chip package according to the third embodiment of the disclosure. FIG. 6 is a schematic top view of an electronic device according to the third embodiment of the disclosure. A process of a chip package 10c according to the present embodiment is similar to the process of the chip package 10a according to the second embodiment, wherein the main difference is that the heat sink 120a in the chip package 10c is further bonded to an electronic device 140. The following only describes the differences between the two embodiments.

Please refer to FIG. 5. According to the present embodiment, the fourth surface 124 of the heat sink 120a is bonded to a bonding region 142 of the electronic device 140, so that the chip 130 is bonded to the electronic device 140 through the chip pad 110 and the heat sink 120a. The heat sink 120a is, for example, bonded to the bonding region 142 of the electronic device 140 by a surface mounting technology (SMT), so that there is, for example, tin paste 150 between the fourth surface 124 of the heat sink 120a and the bonding region 142 of the electronic device 140. It should be noted that according to the present embodiment, the electrical device 140 is, for example, a circuit board or a functional system, so that a shortest distance A between the electronic device 140 and the fourth surface 124 of the heat sink 120a is from 0.05 mm to 0.15 mm. The electronic device 140 and the heat sink 120a are hence close to and are attached to each other. However, according to another embodiment (not shown), when the electronic device 140 is a test pad or another device, the electronic device 140 contacts, for example, the fourth surface 124 of the heat sink 120a.

Please refer to FIG. 6. According to the present embodiment, the bonding region 142 of the electronic device 140 has at least one through hole 144 which exposes the heat sink 120a after the heat sink 120a is bonded to the electronic device 140. The through hole 144 enhances bonding abilities of the electronic device 140 to ground and enhances heat dissipation paths and heat dissipation effectiveness of the heat sink 120a. Moreover, during rework, the chip package 10c may be directly disassembled through the through hole 144, so that damage to the structure of the chip package 10c is prevented and rework efficiency is enhanced.

Still referring to FIG. 6, according to the present embodiment, the electronic device 140 further includes a plurality of solder pads 146 arranged in an array in the bonding region 142. For example, the solder pads are arranged in 3×3, 4×4 arrays or arrays of other numbers. The solder pads 146 arranged in an array cause the solder points of the electronic device 140 for bonding with the heat sink 120a to be dispersed in a uniform manner and is beneficial to the distribution of the tin paste 150 between the heat sink 120a and the electronic device 140, so that the bonding reliability between the heat sink 120a and the electronic device 140 is enhanced and the electrical connection effects between the two is ensured. In addition, from a rework point of view, since the heat sink 120a and the electronic device 140 are bonded through the solder pads 146 which have a smaller area, the heat sink 120a and the electronic device 140 are separable under a lower temperature, thereby enhancing rework efficiency and preventing damage to the chip package caused by a temperature required for disassembly. Although the present embodiment is described as using the electronic device 140 which has a structure as shown in FIG. 6, the electronic device is not limited to this configuration by the disclosure. In other words, the heat sink may be electrically connected to any electronic device.

According to the present embodiment, the chip, the lead frame, and the heat sink are well electrically connected and have superb heat dissipating abilities. Therefore, the chip achieves superb electrical connections to the electronic device through the bottom surface of the heat sink. In other words, the chip is easily integrated with the electronic device to provide other functions, so that products that utilize the chip package are more competitive.

In order to further enhance the electrical connections and heat dissipating abilities between the heat sink and the chip pad and between the heat sink and the electronic device, a surface treatment may be performed on the heat sink prior to bonding the chip pad and the heat sink. Steps of the surface treatment are described in detail in the fourth embodiment.

### Fourth Embodiment

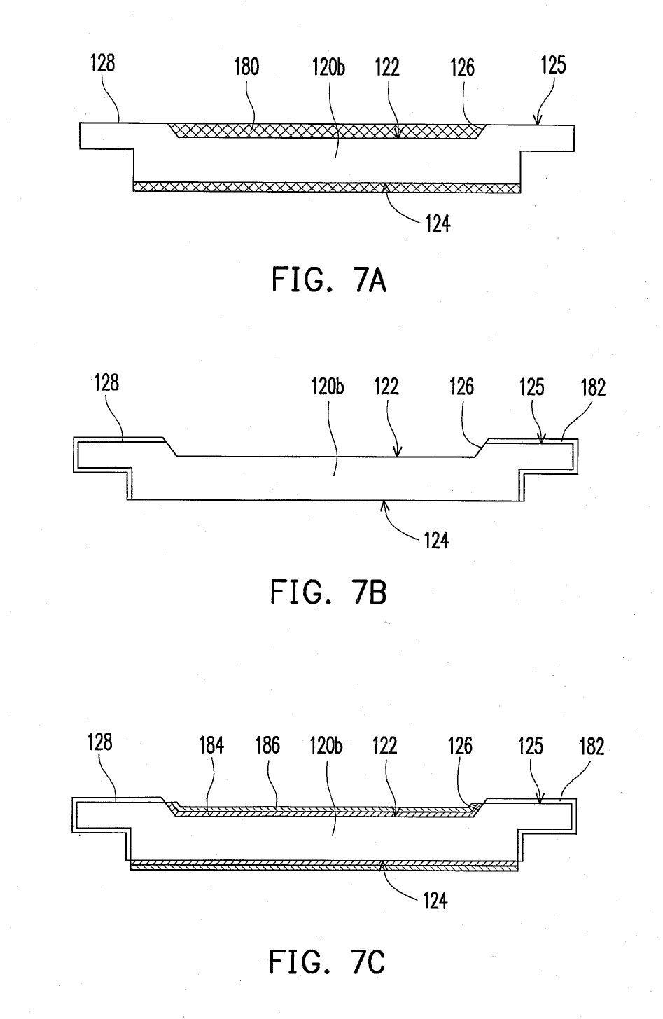

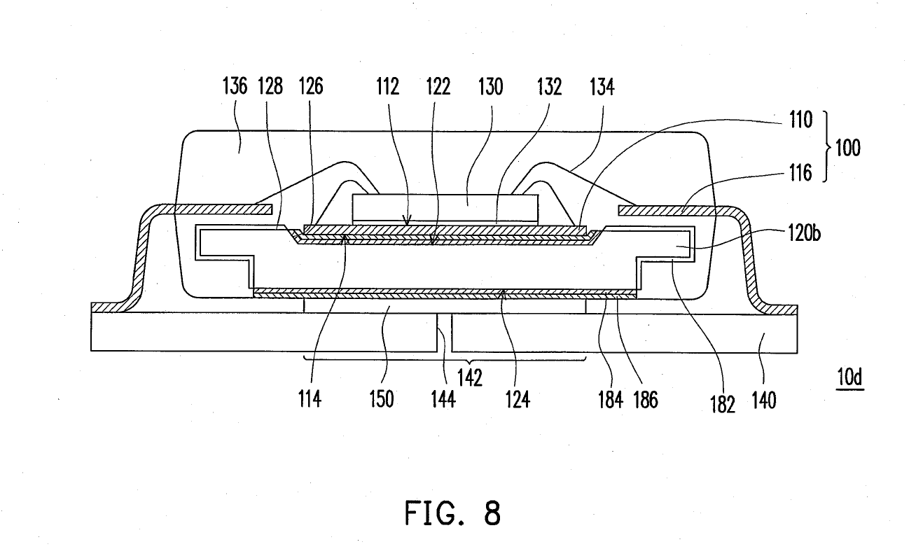

FIGS. 7A to 7C are schematic cross-sectional views which show a process of a heat sink according to the fourth embodiment of the disclosure. FIG. 8 is a schematic cross-sectional view of a chip package according to the fourth embodiment of the disclosure.

Please refer to FIG. 8. A process of a chip package 10d according to the present embodiment is similar to the process of the chip package 10c according to the third embodiment, wherein the main difference is that the following steps are performed to a heat sink 120b before disposing the lead frame 100 on the third surface 122 of the heat sink 120b.

Please refer to FIG. 7A. First, a masking layer 180 is used to mask the central region 126 and the fourth surface 124 of the heat sink 120b and to expose a remaining surface 125 of the heat sink 120b. The remaining surface 125 is the surface that is not masked by the masking layer 180 and includes the peripheral region 128. According to the present embodiment, a material of the heat sink 120b is, for example, aluminum or an aluminum alloy, and the masking layer 180 is, for example, a tape. It should be noted that although according to the present embodiment, the heat sink 120b in which the central region 126 is the lowered region is processed, the process described according to the present embodiment may also be applied to other heat sinks in the disclosure, such as the heat sink 120 according to the first embodiment.

Please refer to FIG. 7B. Next, the remaining surface 125 of the heat sink 120b undergoes an insulating process, so that an insulation layer 182 is formed on the remaining surface 125 (including the peripheral region 128). According to the present embodiment, the heat sink 120b in which a material is aluminum is placed in an electrolyte solution for anodizing process, so that the formed insulation layer 182 is, for example, aluminum oxide. According to another embodiment, the insulating process may be performed by attaching an insulation tape on the remaining surface 125 or by selectively electroplating the remaining surface 125.

Afterwards, the masking layer 180 is removed and the heat sink 120b is washed. According to an embodiment, the process performed on the heat sink may include only the steps shown in FIGS. 7A and 7B. According to the present embodiment, the steps shown in FIG. 7C are further performed on the heat sink.

Please refer to FIG. 7C. Through a process such as electroplating, an electrically conductive layer 184 and an anti-oxidizing electrically conductive layer 186 are sequentially formed on the central region 126 and the fourth surface 124 of the heat sink 120b. The electrically conductive layer 184 is electrically conductive and is capable of being plated with tin, so that the electrically conductive layer 184 is able to facilitate steps such as tin or tin-bismuth electroplating and performing an SMT on the fourth surface 124 with the lead frame 100 after the fourth surface 124 has been packaged, and the anti-oxidizing electrically conductive layer 186 is an anti-oxidizing layer that prevents the electrically conductive layer 184 from being oxidized during subsequent packaging processes. According to the present embodiment, a material of the electrically conductive layer 184 is, for example, copper, and a material of the anti-oxidizing electrically conductive layer 186 is, for example, nickel that prevents copper from being oxidized, wherein a method of forming the anti-oxidizing electrically conductive layer 186 is, for example, electrolysis electroplating or chemical electroplating. Although according to the present embodiment, the electrically conductive layer 184 and the anti-oxidizing electrically conductive layer 186 are sequentially formed on the third surface 122 and the fourth surface 124 of the heat sink 120b, according to other embodiments, it is possible to only form the electrically conductive layer 184 or the anti-oxidizing electrically conductive layer 186 on the third surface 122 and the fourth surface.

Please refer to FIG. 8. After forming the heat sink 120b shown in FIG. 7C, the heat sink 120b is bonded to the lead frame 100 and the electronic device 140, so that a chip package 10d is formed. In the chip package 10d, the electrically conductive layer 184 ensures electrical connection effects between the heat sink 120b and the chip pad 110 and between the heat sink 120b and the electronic device 140, and the electrically conductive layer 184 is able to facilitate steps such as tin or tin-bismuth electroplating and performing an SMT on the fourth surface 124 with the lead frame 100 after the fourth surface 124 has been packaged, and the anti-oxidizing electrically conductive layer 186 prevents the electrically conductive layer 184 from being oxidized during subsequent packaging processes. The insulation layer 182 prevents the heat sink 120b from contacting the leads 116 and causing problems such as electrical leakage and short circuits, so that there are superb electrical connections between the heat sink 120b and the chip pad 110 and between the heat sink 120b and the electronic device 140. The chip 130 is hence able to be integrated with the electronic device 140 to provide other functions, so that products which utilize the chip package 10d are more competitive.

### Fifth Embodiment

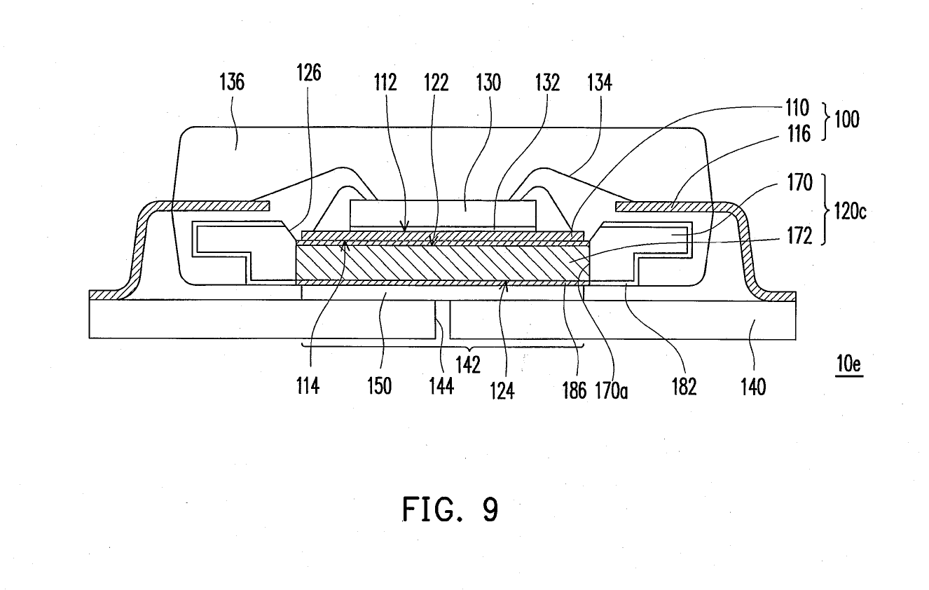

FIG. 9 is a schematic cross-sectional view of a chip package according to the fifth embodiment of the disclosure. According to the present embodiment, structures and processes of a chip package 10e are similar to those of the chip package 10c according to the third embodiment. The following only describes the differences in between.

According to the present embodiment, a heat sink 120c includes a first portion 170 and a second portion 172, wherein a center of the first portion 170 is a hollowed portion 170a, and the second portion 172 is embedded in the hollowed portion 170a of the first portion 170, so that the chip pad 110 and the electronic device 140 are respectively bonded to the surfaces 122 and 124 of the second portion 172. A material of the first portion 170 is, for example, aluminum. A material of the second portion 172 is, for example, a material which is electrically conductive and able to be plated with tin, such as copper. According to the present embodiment, after the second portion 172 is embedded in the first portion 170, an insulating process in exemplarily performed on a surface of the first portion 170 which is exposed, so that the insulation layer 182 is formed. The insulating process may include attaching a tape on a surface of the first portion 170 or selectively electroplating or performing an anodizing process on the surface of the first portion 170. A material of the insulation layer 182 is, for example, aluminum oxide. In addition, according to the present embodiment, electrolysis electroplating or chemical electroplating is performed on the surfaces 122 and 124 of the second portion that are exposed, so that the anti-oxidizing electrically conductive layer 186 is formed on the surfaces 122 and 124. A material of the anti-oxidizing electrically conductive layer 186 is, for example, nickel.

According to the present embodiment, the second portion 172 is electrically conductive and is able to be plated with tin, so that the second portion 172 is able to facilitate steps such as tin or tin-bismuth electroplating and performing an SMT on the fourth surface 124 with the lead frame 100 after the fourth surface 124 has been packaged. The anti-oxidizing electrically conductive layer 186 on the surfaces 122 and 124 of the second portion 172 prevent the second portion 172 form being oxidized during subsequent packaging processes. The insulation layer 182 prevents the heat sink 120c from contacting the leads 116 and causing problems such as electrical leakage and short circuits. Therefore, there are superb electrical connections between the heat sink 120c and the chip pad 110 and between the heat sink 120c and the electronic device 140. The chip 130 is hence able to be integrated with the electronic device to provide other functions, so that products which utilize the chip package 10e are more competitive.

It should be noted that according to the fourth and fifth embodiments, the chip packages 10d and 10e include the electronic device 140. However, it is possible that the chip packages 10d and 10e do not include the electronic device 140, meaning that the fourth surface 124 of the heat sinks 120b and 120c is directly exposed.

In summary, according to the disclosure, there are superb electrical connections in the chip package and between the chip, the lead frame, and the heat sink used in the chip package process, and the bottom surface of the heat sink is exposed. Therefore, the chip package has superb heat dissipating abilities and the chip is able to be connected to ground, to a power source, or to a signal through the bottom surface of the heat sink. Therefore, the leads that were originally used for functions such as connecting to ground, to a power source, and to a signal may be used for additional functions, thereby increasing the variety of circuit designs. In addition, the chip is able to be electrically connected to other electronic devices through the bottom surface of the heat sink, so as to have superb electrical connections to other electronic devices. In other words, the chip package provided by the disclosure has superb heat dissipating abilities and provides additional functions and is suitable for being integrated with other electronic devices, so that product which utilize this chip package are more competitive.

It will be apparent to those skilled in the art that various modifications and variations can be made to the structure of the disclosed embodiments without departing from the scope or spirit of the disclosure. In view of the foregoing, it is intended that the disclosure cover modifications and variations of this disclosure provided they fall within the scope of the following claims and their equivalents.

What is claimed is:

1. A chip package, comprising:
a lead frame, comprising a chip pad and a plurality of leads, wherein the chip pad has a first surface and a second surface which are opposite to each other;
a heat sink, having a third surface and a fourth surface which are opposite to each other, wherein the lead frame is disposed on the third surface of the heat sink through the second surface of the chip pad, and the fourth surface of the heat sink is exposed;
a chip, disposed on the first surface of the chip pad and electrically connecting the chip to each of the chip pad and the leads; and
a molding compound, encapsulating the chip, the chip pad, the heat sink, and a portion of each of the leads.

2. The chip package as claimed in claim 1, further comprising an electronic device, wherein a bonding region of the electronic device is bonded to the fourth surface of the heat sink, so that the chip is electrically connected to the electronic device through the chip pad and the heat sink.

3. The chip package as claimed in claim 2, wherein the heat sink and the electronic device are bonded by a surface mounting technology.

4. The chip package as claimed in claim 2, wherein the bonding region of the electronic device has at least one through hole, so that the heat sink is exposed after the heat sink is bonded to the electronic device.

5. The chip package as claimed in claim 2, wherein the electronic device comprises a circuit board, a testing pad, or a functional system.

6. The chip package as claimed in claim 5, wherein the circuit board comprises a plurality of solder pads arranged in an array in the bonding region.

7. The chip package as claimed in claim 2, wherein a shortest distance between the electronic device and the fourth surface of the heat sink is from 0.05 mm to 0.15 mm.

8. The chip package as claimed in claim 2, wherein the electronic device contacts the fourth surface of the heat sink.

9. The chip package as claimed in claim 1, further comprising an electrically conductive layer between the chip pad and the heat sink.

10. The chip package as claimed in claim 9, wherein the electrically conductive layer is a bonding glue or an electrically conductive tape.

11. The chip package as claimed in claim 1, wherein the heat sink has a central region and a peripheral region surrounding the central region, the central region is an electrically conductive region, the peripheral region is an insulation region, and the chip pad is disposed on the central region.

12. The chip package as claimed in claim 11, wherein the central region is a lowered region and the peripheral region is a level region, the lowered region has a depth, there is a height difference between the chip pad and a top of the leads, and the depth is less then the height difference.

13. The chip package as claimed in claim 12, wherein the depth of the lowered region is greater than 0 mm and less than 0.294 mm.

14. The chip package as claimed in claim 11, wherein an electrically conductive layer is disposed on the central region and the fourth surface of the heat sink.

15. The chip package as claimed in claim 14, wherein the electrically conductive layer is formed by an electroplating process.

16. The chip package as claimed in claim 14, wherein a material of the electrically conductive layer comprises copper.

17. The chip package as claimed in claim 14, wherein an anti-oxidizing layer is further disposed on the electrically conductive layer.

18. The chip package as claimed in claim 17, wherein the anti-oxidizing layer is formed by electrolysis electroplating or chemical electroplating.

19. The chip package as claimed in claim 17, wherein a material of the anti-oxidizing layer comprises nickel.

20. The chip package as claimed in claim 11, wherein an insulation tape is attached on the peripheral region.

21. The chip package as claimed in claim 11, wherein selective electroplating or an anodizing process is performed on the peripheral region.

22. The chip package as claimed in claim 1, wherein selective electroplating or an anodizing process is performed on a remaining surface other than the third surface and the fourth surface of the heat sink.

23. The chip package as claimed in claim 1, wherein an insulating tape is attached on a remaining surface other than the third surface and the fourth surface of the heat sink.

24. The chip package as claimed in claim 1, wherein the heat sink comprises a first portion and a second portion, a center of the first portion is a hollowed portion, the second portion is embedded in the hollowed portion of the first portion, and the chip pad is bonded to the second portion.

25. The chip package as claimed in claim 24, wherein a material of the first portion comprises aluminum.

26. The chip package as claimed in claim 24, wherein a material of the second portion comprises a material which is electrically conductive and able to be plated with tin.

27. The chip package as claimed in claim 24, wherein a material of the second portion comprises copper.

28. The chip package as claimed in claim 24, wherein an anti-oxidizing layer is disposed on a surface of the second portion.

29. The chip package as claimed in claim 28, wherein a method of forming the anti-oxidizing layer comprises electrolysis electroplating or chemical electroplating.

30. The chip package as claimed in claim 28, wherein a material of the anti-oxidizing layer comprises nickel.

31. The chip package as claimed in claim 24, wherein an insulating process is performed on a surface of the first portion.

32. The chip package as claimed in claim 31, wherein the insulating process comprises attaching an insulation tape on a surface of the first portion.

33. The chip package as claimed in claim 31, wherein the insulating process comprises selectively electroplating or performing an anodizing process on the surface of the first portion.
